(19) United States
(12) Patent Application Publication
(10) Pub. No.: US 2016/0268384 A1
(43) Pub. Date: Sep. 15, 2016

(54) METHOD FOR PREPARING A NANO-SCALE FIELD-EFFECT TRANSISTOR

(71) Applicant: PEKING UNIVERSITY, Beijing (CN)

(72) Inventors: Ming Li, Beijing (CN); Jiewen Fan, Beijing (CN); Yuancheng Yang, Beijing (CN); Haoran Xuan, Beijing (CN); Ru Huang, Beijing (CN)

(21) Appl. No.: 15/030,510

(22) PCT Filed: Apr. 24, 2015
(86) PCT No.: PCT/CN2015/077395

§ 371 Date: Apr. 19, 2016

(30) Foreign Application Priority Data
Sep. 26, 2014 (CN) 201410502998.5

(51) Int. Cl. H01L 29/40; H01L 29/06; H01L 21/3205; H01L 21/265; H01L 21/308; H01L 21/02; H01L 29/66; H01L 21/321

(52) U.S. Cl. CPC H01L 29/401; H01L 29/66477; H01L 29/0665; H01L 29/0649; H01L 21/32105; H01L 21/26513; H01L 21/3081; H01L 21/02532; H01L 21/32051; H01L 21/3212

(57) ABSTRACT

The present invention discloses a method for preparing a nano-scale field-effect transistor, and belongs to the field of large-scale integrated circuit manufacturing technologies. The method focuses on preparing a nano-scale field-effect transistor on an SOI substrate by epitaxial growth. In the invention, the material and appearance of a channel of a nano-scale device may be accurately controlled by using an epitaxy process, and the device performance may be further optimized; moreover, a threshold voltage may be flexibly adjusted to adapt for requirements of different IC designs by realizing different channel doping types and doping concentrations; also, a gate structure with a consistent width in a height direction may be obtained, the parasitism and fluctuation of the device may be reduced, and at the same time, the method can be well compatible with CMOS post-gate processes, and is simple in procedure and low in cost. The method may be applied to the integration of future large-scale semiconductor devices.

### FIELD OF THE INVENTION

The present invention relates to a field of large-scale integrated circuit manufacturing technologies, and in particular, to a method for preparing a nano-scale field-effect transistor on an SOI substrate by epitaxial growth.

### BACKGROUND OF THE INVENTION

At present, the semiconductor manufacture develops rapidly under the guide of Moore law. The power consumption needs to be reduced as much as possible at the same time that the performance and integration density of an integrated circuit are improved continuously. It is a focal point of the future semiconductor manufacture to prepare an ultrashort channel device with high-performance and low-power consumption. After entering the 22 nm technical node, in order to overcome the above problem, multi-gate structure devices become the hot spot of the current semiconductor devices. Intel has applied such a structure in the 22-nm products since last year, and it has exhibited advantages of high performance and low power consumption. Among numerous multi-gate structure devices, a surrounding-gate device has a great potentiality due to its excellent short channel control ability and ballistic transport ability, and becomes one of devices that are most possibly applied in the technical node of the subsequent semiconductor manufacture.

However, an accurate control on the size and sectional appearance of a channel of a nano-scale device is a great challenge in the preparation process. If a high-mobility channel can be realized based on the existing CMOS process, the device performance will be further improved. Additionally, it is an urgent requirement for IC design to realize multiple thresholds in the nano-scale device. Therefore, it is very difficult in the prior art to obtain a gate line with a consistent width in a height direction, and this will add the fluctuation and parasitism effect of the device.

### SUMMARY OF THE INVENTION

Therefore, it is an object of the present invention to provide a method for preparing a nano-scale field-effect transistor on an SOI substrate by epitaxial growth for an ultrashort channel device with high-performance and low-power consumption. The technical solution of preparing a nano-scale field-effect transistor by epitaxial growth according to the invention is as follows:

1) thinning a silicon substrate by a thinning process on an SOI substrate, which specifically includes:

a) forming a sacrificial oxide layer on an SOI silicon substrate by dry-oxygen oxidation, and thinning a silicon film to a certain thickness; and

b) removing the sacrificial oxide layer by HF solution wet corrosion;

2) forming source-drain doping by ion implantation, annealing and activation;

a) doping the SOI silicon substrate by ion implantation; and

b) activating and annealing impurity by rapid thermal annealing (RTP);

3) forming a silicon hairline structure by photoetching, and stopping on an oxidation isolation layer;

a) forming a hairline pattern by electron beam photoetching;

b) anisotropically dry-etching the oxidation isolation layer on the SOI silicon substrate to form a silicon hairline structure;

4) depositing and planarizing a dielectric material as a source-drain hard mask layer;

a) depositing silicon oxide by chemical vapor deposition (CVD) as the source-drain hard mask layer; and

b) planarizing the source-drain hard mask layer by chemical-mechanical polishing (CMP);

5) selecting an etching rate of the dielectric material which is the same as that of silicon on the source-drain hard mask layer, etching the source-drain hard mask layer and the silicon hairline by using photoetching, and stopping on the oxidation isolation layer to form a gate line groove;

a) forming a groove pattern by electron beam photoetching;

b) etching the source-drain hard mask layer to the oxidation isolation layer, wherein the etching rate thereof is the same as the etching rate of silicon, and the silicon hairline is completely etched; and

c) etching the oxidation isolation layer by a certain thickness, and forming the groove;

6) performing selective epitaxy by using silicon substrate windows exposed on two sides of the groove, and reforming a channel of a device;

a) forming the channel of the device by selective epitaxy; and

b) activating and annealing impurity by rapid thermal annealing (RTP);

7) depositing a high-k gate dielectric, and then depositing and planarizing a metal gate material to form a gate stacked structure;

a) forming a silicon oxide interfacial layer by dry-oxygen oxidation;

b) depositing high hafnium oxide as a gate dielectric layer by atom layer deposition technology (ALD);

c) depositing titanium nitride as a metal gate work function layer by physical vapor deposition technology (PVD);

d) depositing aluminum as a metal gate layer by physical vapor deposition technology (PVD); and

e) planarizing the aluminum metal gate layer to the source-drain hard mask layer by chemical mechanical polishing technology (CMP);

8) forming a metal contact, thereby completing the preparation of a field-effect transistor;

a) forming a metal contact via pattern by electron beam photoetching;

b) etching the source-drain hard mask layer to the oxidation isolation layer to expose the initial silicon hairline source-drain so as to form a source-drain contact hole;

c) depositing a metal as a metal contact layer by physical vapor deposition technology (PVD); and

d) planarizing the metal contact layer to the source-drain hard mask layer by chemical-mechanical polishing technology (CMP).

In the method for preparing a nano-scale field-effect transistor on an SOI substrate by epitaxial growth according to the invention, the material and appearance of a channel of a nano-scale device may be accurately controlled by using an epitaxy process, and the device performance may be further optimized; next, a threshold voltage may be flexibly adjusted so as to adapt for requirements of different IC designs by realizing different channel doping types and doping concentrations; and finally, a gate structure with a consistent width in a height direction may be obtained, the parasitism and fluctuation of the device may be reduced, and at the same time, the method can be well compatible with CMOS post-gate processes, and is simple in procedure and low in cost. Therefore, the method has a great potentiality to be applied to the integration of future large-scale semiconductor devices.

### BRIEF DESCRIPTION OF THE DRAWINGS

FIGS. 1-15 show a flow chart of a specific embodiment of a method for preparing a nano-scale field-effect transistor on an SOI substrate by epitaxial growth according to the invention; and

FIG. 16 illustrates the used material.

### DETAILED DESCRIPTION OF THE EMBODIMENTS

The specific implementation of a method for preparing a nano-scale field-effect transistor on an SOI substrate by epitaxial growth according to the invention will be described as follows, by taking a silicon substrate as an example:

1) Thinning an SOI Silicon Substrate

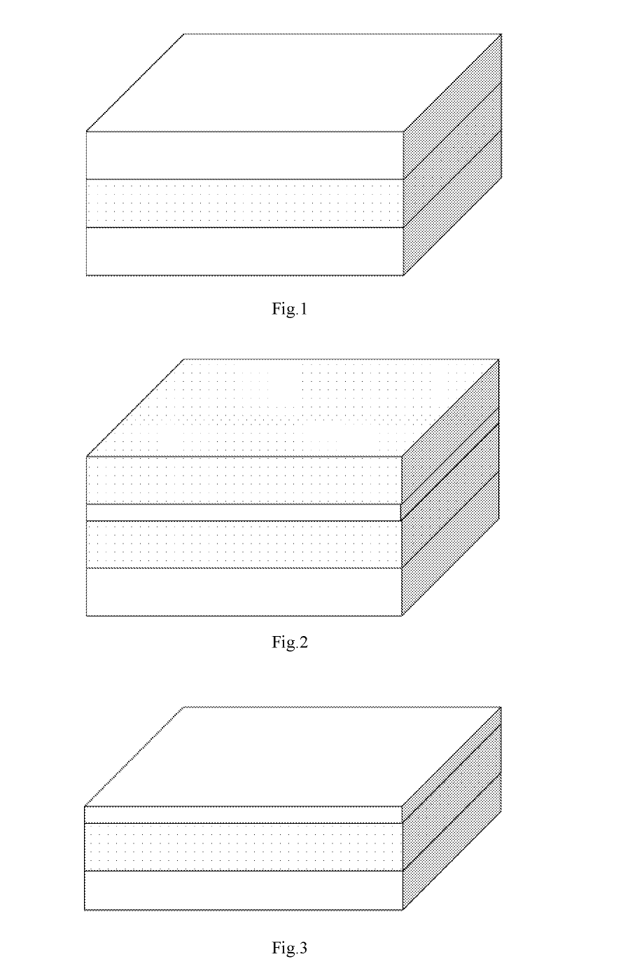

a) A thickness of the SOI silicon substrate is 1000 Å, as shown in FIG. 1;

b) A sacrificial oxide layer of 1800 Å is formed on the SOI silicon substrate by dry-oxygen oxidation, and a silicon film is thinned to 200 Å, as shown in FIG. 2; and

c) The sacrificial oxide layer of 1800 Å is removed by HF solution wet corrosion, as shown in FIG. 3;

2) Source-Drain Doping

a) The SOI silicon substrate is doped by P-type impurity with a dosage of 1×10¹⁵ cm⁻² through ion implantation;

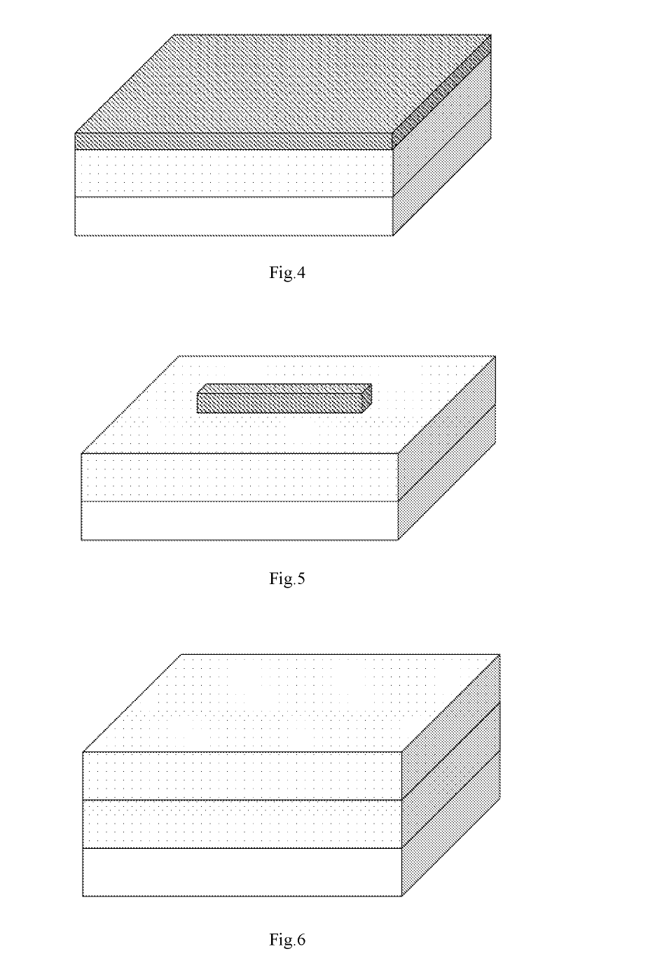

b) Impurity is activated and annealed by performing rapid thermal annealing (RTP) at 950° C. for 5 s, as shown in FIG. 4;

3) Silicon Hairline Structure

a) A hairline pattern with a width of 20 nm is formed by electron beam photoetching;

b) The SOI silicon substrate is anisotropically dry-etched by 200 Å to an oxidation isolation layer, so as to form a silicon hairline structure with a width of 20 nm, as shown in FIG. 5;

4) Source-Drain Hard Mask Layer

a) Silicon oxide is deposited to 2000 Å as a source-drain hard mask layer by chemical vapor deposition (CVD);

b) The silicon oxide is polished to 1000 Å by chemical-mechanical polishing (CMP), and the source-drain hard mask layer is planarized, as shown in FIG. 6;

5) Gate Line Groove

a) A groove pattern with a width of 20 nm is formed by electron beam photoetching;

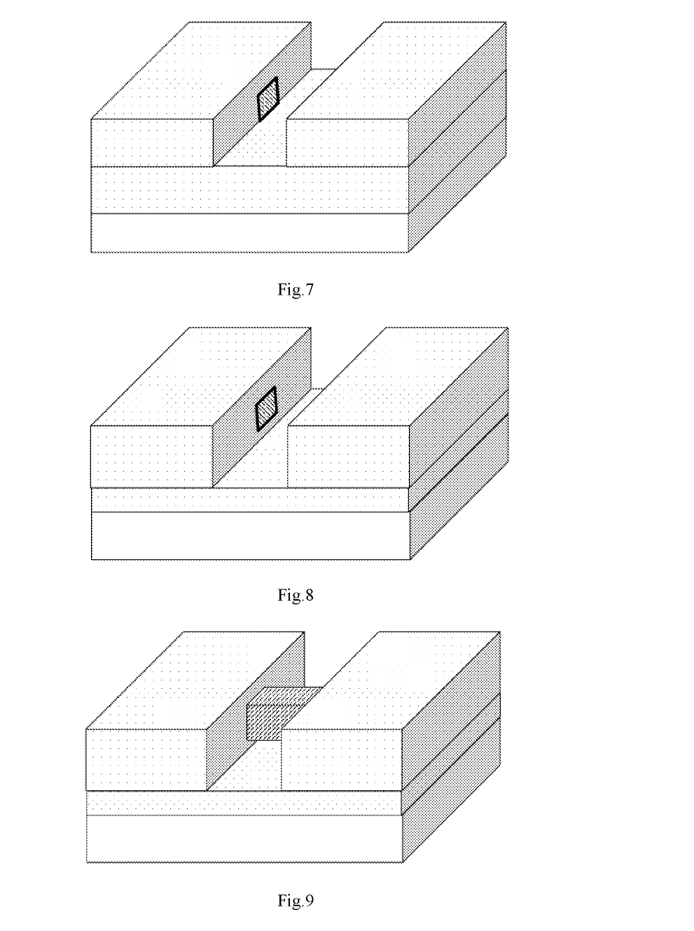

b) The source-drain hard mask layer is anisotropically dry-etched by 1000 Å, and an etching rate thereof is the same as that of silicon, thus the silicon hairline with a height of 200 Å is also etched completely, as shown in FIG. 7;

c) The oxidation isolation layer is anisotropically dry-etched by 300 Å and it is stopped on the oxidation isolation layer to form a groove with a width of 20 nm, as shown in FIG. 8;

6) Reforming a Channel of a Device

a) The silicon is selectively epitaxial grown by 100 Å to form a silicon device channel with a height of 40 nm, a width of 40nm and a length of 20 nm, and in-situ doping is performed with a doped impurity of boron and a doped concentration of 1×10¹⁸ cm⁻³; and

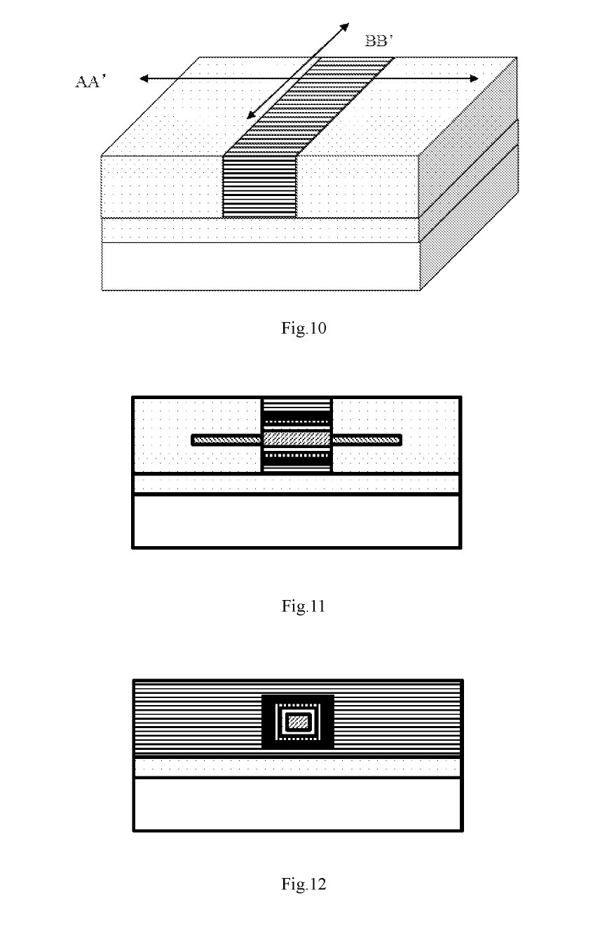

b) The impurity is activated and annealed by performing rapid thermal annealing (RTP) at 950 ° C. for 5 s, as shown in FIG. 9;

7) Gate Stacked Structure

a) A silicon oxide interfacial layer is formed to 10 Å by dry-oxygen oxidation;

b) High hafnium oxide is deposited to 20 Å as a gate dielectric layer by atom layer deposition technology (ALD);

c) Titanium nitride is deposited to 200 Å as a metal gate work function layer by physical vapor deposition technology (PVD);

d) Aluminum is deposited to 2000 Å as a metal gate layer by physical vapor deposition technology (PVD); and

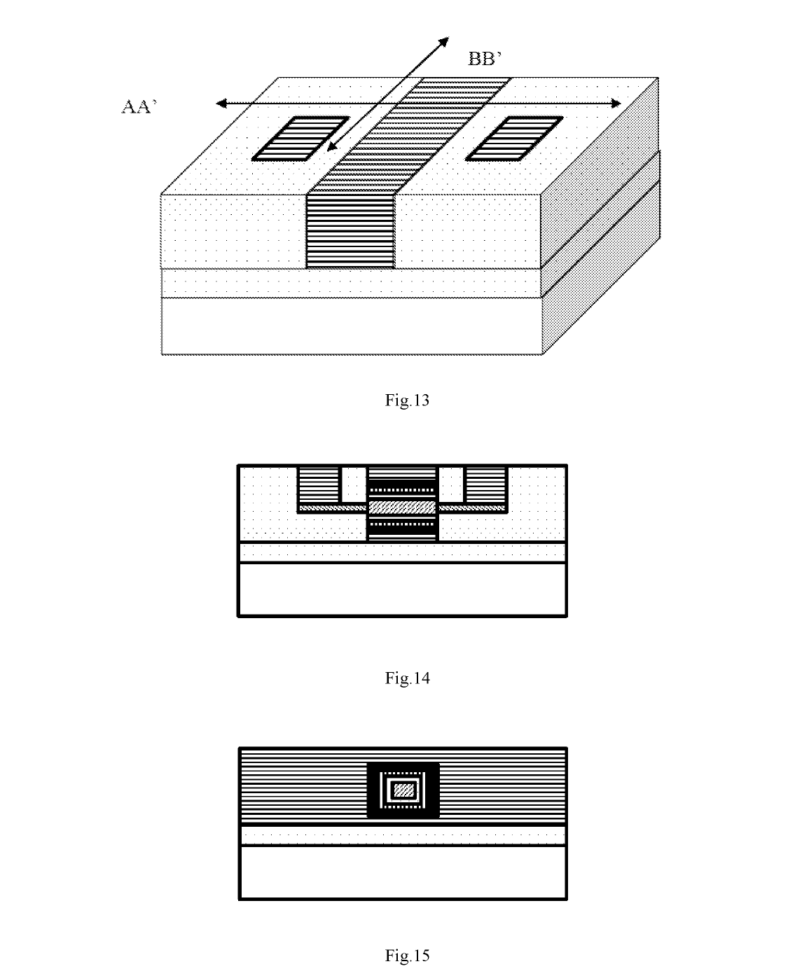

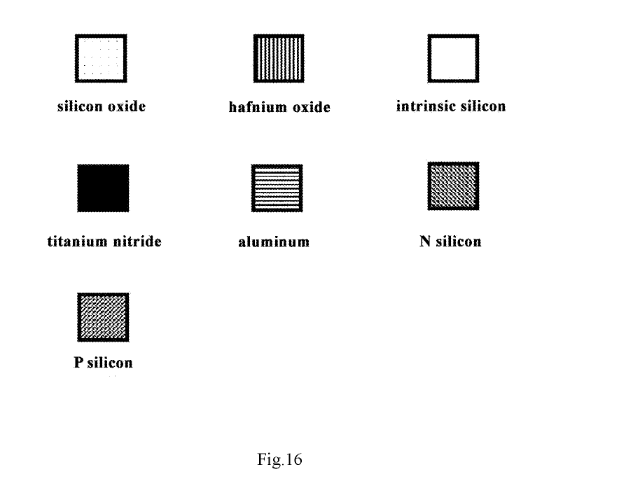

e) The aluminum metal gate layer is planarized to the source-drain hard mask layer by chemical-mechanical polishing technology (CMP), as shown in FIG. 10, wherein FIG. 11 is a sectional view of FIG. 10 in direction AA′, and FIG. 12 is a sectional view of FIG. 10 in direction BB′;

8) Metal Contact

a) A square via with a size of 100 nm×100 nm is photoetched as a metal contact pattern;

b) The source-drain hard mask layer is anisotropically dry-etched by 1200 Å and it is stopped on the oxidation isolation layer, so as to expose an initial silicon hairline source-drain to form a source-drain contact hole;

c) Aluminum is deposited to 2000 Å as a metal contact layer by physical vapor deposition technology (PVD); and

d) The aluminum metal contact layer is planarized to the source-drain hard mask layer by chemical-mechanical polishing technology (CMP), as shown in FIG. 13, wherein FIG. 14 is a sectional view of FIG. 13 in direction AA′, and FIG. 15 is a sectional view of FIG. 13 in direction BB′.

The embodiment described above is not used for limiting the invention. Various variations and modifications may be made by those skilled in the art without departing from the spirit and scope of the invention. Therefore, the protection scope of the invention is defined by the scope of the claims.

What is claimed is:

1. A preparation method for a nano-scale field-effect transistor, comprising:
(a) thinning a silicon substrate with a thinning process on an SOI substrate;
(b) forming source-drain doping by ion implantation, annealing and activation;
(c) forming a silicon hairline structure by photoetching, and stopping on an oxidation isolation layer;
(d) depositing and planarizing a dielectric material as a source-drain hard mask layer;
(e) selecting an etching rate of the dielectric material which is the same as that of silicon on the source-drain hard mask layer, etching the source-drain hard mask layer and the silicon hairline by photoetching, and stopping on the oxidation isolation layer to form a gate line groove;
(f) performing selective epitaxy by using silicon substrate windows exposed on two sides of the groove, and reforming a channel of a device;
(g) depositing a high-k gate dielectric, and then depositing and planarizing a metal gate material to form a gate stacked structure; and
(h) forming a metal contact, thereby completing the preparation of a field-effect transistor.

2. The preparation method according to claim 1, wherein, the thinning process in step (a) is sacrificial oxidation thinning.

3. The preparation method according to claim 1, wherein, the silicon hairline structure in step (c) is a fin-type structure with a large aspect ratio, or a strip-type structure with a small aspect ratio, or a square nano-line structure in which a height is consistent with a width.

4. The preparation method according to claim 1, wherein, the dielectric material in step (d) is silicon oxide or silicon nitride.

5. The preparation method according to claim 1, wherein, the etching in step (e) stops on the oxidation isolation layer, if the oxidation isolation layer is not etched, a three-gate structure device is formed finally; if the oxidation isolation layer is etched by a certain depth, a surrounding-gate structure device is formed finally.

6. The preparation method according to claim 1, wherein, a material for selective epitaxy in step (f) is silicon or germanium silicon.

7. The preparation method according to claim 1, wherein, a doping for selective epitaxy in step (f) is N or P type doping.

8. The preparation method according to claim 1, wherein, the high-k metal gate stacked structure in step (g) comprises:
g-1) forming an interfacial layer by dry-oxygen oxidation or solution wet oxidation;
g-2) depositing a high-k gate dielectric layer by atom layer deposition technology;
g-3) depositing a metal gate work function layer by physical vapor deposition technology;
g-4) depositing a metal gate layer by physical vapor deposition technology; and
g-5) planarizing the metal gate layer to the source-drain hard mask layer by chemical mechanical polishing technology.

9. The preparation method according to claim 1, wherein, the metal contact structure in step (h) comprises:
h-1) forming a metal contact via pattern by electron beam photoetching;
h-2) etching the source-drain hard mask layer to the oxidation isolation layer to expose an initial silicon hairline source-drain so as to form a source-drain contact hole;
h-3) depositing a metal contact as a metal contact layer by physical vapor deposition technology; and
h-4) planarizing the metal contact layer to the source-drain hard mask layer by chemical mechanical polishing technology.
